(19) United States
(12) Patent Application Publication
(10) Pub. No.: US 2025/0366279 A1
(43) Pub. Date: Nov. 27, 2025

(54) CONTACT STRUCTURES FOR SUBMOUNTS IN LIGHT-EMITTING DIODE DEVICES

(71) Applicant: CreeLED, Inc., Durham, NC (US)

(72) Inventors: David Suich, Durham, NC (US); Michael Check, Holly Springs, NC (US); Thomas Celano, Cary, NC (US); Joseph G. Sokol, Durham, NC (US); Colin Blakely, Raleigh, NC (US)

(21) Appl. No.: 18/670,372

(22) Filed: May 21, 2024

(51) Int. Cl. H01L 33/62

(52) U.S. Cl. CPC H10H 20/857; H10H 20/0364

(57) ABSTRACT

Light-emitting devices and more particularly contact structures for submounts in light-emitting diode (LED) devices are disclosed. Exemplary devices include LED chips with active LED structures bonded to carrier submounts. Contact structures include arrangements of mounting pads of carrier submounts relative to contacts of active LED structures that improve bonding integrity and/or mitigate stress-related deformation in active LED structures where growth substrates are removed. Exemplary contact structures include differing heights between anode and cathode mounting pads, particularly greater heights for mounting pads with smaller surface areas to ensure suitable bonding contact. Additional contact structures include arrangements of contacts and corresponding mounting pads that position bonding interfaces about various areas of LED chips that mitigate and/or counterbalance certain areas prone to stress-related deformation.

### FIELD OF THE DISCLOSURE

The present disclosure relates to light-emitting devices and more particularly to contact structures for submounts in light-emitting diode devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new LED display and general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, indium phosphide, aluminum nitride, gallium arsenide-based materials, and/or from organic semiconductor materials.

LED packages have been developed that may provide mechanical support, electrical connections, and encapsulation for LED emitters. LED chips and LED packages have also been developed for use in LED arrays of closely spaced LED chips or packages. LED chips and LED packages are further being developed with reduced sizes for many applications. Challenges exist in producing high quality light with desired emission characteristics while also providing suitable mechanical support and electrical connections, among other packaging arrangements.

The art continues to seek improved LEDs and solid-state lighting devices having desirable illumination characteristics capable of overcoming challenges associated with conventional lighting devices.

### SUMMARY

The present disclosure relates to light-emitting devices and more particularly to contact structures for submounts in light-emitting diode (LED) devices. Exemplary devices include LED chips with active LED structures bonded to carrier submounts. Contact structures include arrangements of mounting pads of carrier submounts relative to contacts of active LED structures that improve bonding integrity and/or mitigate stress-related deformation in active LED structures where growth substrates are removed. Exemplary contact structures include differing heights between anode and cathode mounting pads, particularly greater heights for mounting pads with smaller surface areas to ensure suitable bonding contact. Additional contact structures include arrangements of contacts and corresponding mounting pads that position bonding interfaces about various areas of LED chips that mitigate and/or counterbalance certain areas prone to stress-related deformation.

In one aspect, an LED chip comprises: a carrier submount comprising a first mounting pad and a second mounting pad, the first mounting pad having a height above the carrier submount that is greater than a height of the second mounting pad above the carrier submount; an active LED structure bonded to the carrier submount, the active LED structure comprising an n-type layer, a p-type layer, and an active layer between the n-type layer and the p-type layer; a first contact electrically coupled to either the p-type layer or the n-type layer, the first contact being bonded to the first mounting pad in a position that is between the active LED structure and the carrier submount; and a second contact electrically coupled to one of the p-type layer or the n-type layer that is different from the first contact, the second contact being bonded to the second mounting pad in a position that is between the active LED structure and the carrier submount. In certain embodiments, a thickness of the first contact is the same as or differs by no more than one half percent of a thickness of the second contact relative to the active LED structure. In certain embodiments, the first contact is an anode contact electrically coupled to the p-type layer and the second contact is a cathode contact electrically coupled to the n-type layer. The LED chip may further comprise an anode bond pad and a cathode bond pad on a side of the carrier submount that is opposite the active LED structure, wherein the anode bond pad forms a shape that is symmetric with the cathode bond pad. In certain embodiments, the first mounting pad and the second mounting pad each comprise a base layer and a protective layer on the base layer. In certain embodiments: the protective layer of the first mounting pad forms a first bonding interface with the first contact; the protective layer of the second mounting pad forms a second bonding interface with the second contact; and a position of the first bonding interface above the carrier submount is greater than a position of the second bonding interface above the carrier submount. The LED chip may further comprise an insulating support layer between the carrier submount and the active LED structure, the insulating support layer positioned between the first and second contacts.

In another aspect, an LED chip comprises: a carrier submount comprising a first mounting pad and a second mounting pad; an active LED structure bonded to the carrier submount, the active LED structure comprising an n-type layer, a p-type layer, and an active layer between the n-type layer and the p-type layer; a first contact electrically coupled to the active LED structure, the first contact being bonded to the first mounting pad; and a second contact electrically coupled to active LED structure, the second contact being bonded to the second mounting pad; the first contact and the second contact forming a nonlinear gap therebetween, the nonlinear gap extending continuously to segregate the first contact from the second contact. In certain embodiments, the first contact and the second contact form interdigitated fingers, and the nonlinear gap extends from one perimeter edge of the first contact to an opposing perimeter edge of the first contact along the interdigitated fingers. In certain embodiments, the first mounting pad and the second mounting pad form corresponding interdigitated fingers. In certain embodiments, the nonlinear gap is continuously curved between opposing perimeter edges of the first contact. In certain embodiments, the first contact is positioned proximate a corner of the active LED structure, and the second contact extends proximate a majority of three perimeter edges of the active LED structure. In certain embodiments, the nonlinear gap is radially curved about a center of the active LED structure. In certain embodiments, the nonlinear gap is radially curved to from a circular shape. The LED chip may further comprise a first bond pad and a second bond pad on a side of the carrier submount that is opposite the active LED structure, wherein the first bond pad forms a shape that is symmetric with the second bond pad.

In another aspect, an LED chip comprises: a carrier submount comprising a plurality of layers, the plurality of layers comprising: a first layer with at least one anode mounting pad and at least one cathode mounting pad; a second layer with at least one anode interconnection electrically coupled to the at least one anode mounting pad and at least one cathode interconnection electrically coupled to the at least one cathode mounting pad; and a third layer with an anode bond pad electrically coupled to the at least one anode interconnection and a cathode bond pad electrically coupled to the at least one cathode interconnection; an active LED structure bonded to the carrier submount; at least one anode contact electrically coupled between the active LED structure and the at least one anode mounting pad; and at least one cathode contact electrically coupled between the active LED structure and the at least one cathode mounting pad. In certain embodiments: the at least one anode mounting pad comprises a plurality of anode mounting pads that form a first array across the first layer; the at least one anode contact comprises a plurality of anode contacts that are bonded to the plurality of anode mounting pads; the at least one cathode mounting pad comprises a plurality of cathode mounting pads that form a second array across the first layer; and the at least one cathode contact comprises a plurality of cathode contacts that are bonded to the plurality of cathode mounting pads. In certain embodiments: the at least one anode interconnection forms a continuous structure electrically coupled to each anode mounting pad of the plurality of anode mounting pads; and the at least one cathode interconnection forms a continuous structure electrically coupled to each cathode mounting pad of the plurality of cathode mounting pads. In certain embodiments: the at least one anode interconnection forms a first plurality of finger extensions; and the at least one cathode interconnection a second plurality of finger extensions that are interdigitated with the first plurality of finger extensions. In certain embodiments, the anode bond pad forms a shape that is symmetric with the cathode bond pad.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view at a fabrication step for forming light-emitting diode (LED) chips at the wafer level according to aspects of the present disclosure.

FIG. 1B is a cross-sectional view at a subsequent fabrication step to FIG. 1A where the LED wafer is bonded to the submount wafer.

FIG. 1C is a cross-sectional view at a subsequent fabrication step to FIG. 1B where the growth substrate of FIG. 1B is removed from the LED wafer.

FIG. 1D is a cross-sectional view at a subsequent fabrication step to FIG. 1C where a top surface of the n-type layer forms a primary light-extracting face for each LED chip.

FIG. 1E is a cross-sectional view at a subsequent fabrication step to FIG. 1D where individual LED chips are separated from one another.

FIG. 1F is a bottom view of one of the LED chips from FIG. 1E.

FIG. 2 is a cross-sectional view of an exemplary one of the LED chips of FIGS. 1A to 1F that exhibits stress-related deformation.

FIG. 3A is a cross-sectional view of an LED chip that is similar to the LED chip of FIGS. 1A to 1F except the anode mounting pad is formed with increased thickness relative to the cathode mounting pad.

FIG. 3B is a cross-sectional view at a subsequent fabrication step for the LED chip after bonding to the carrier submount and removal of the growth substrate.

FIG. 4A is a simplified cross-sectional view of the LED chip of FIGS. 3A and 3B with an enlarged portion illustrating further details of the anode and cathode mounting pads.

FIG. 4B is a cross-sectional view at a subsequent fabrication step for the LED chip of FIG. 4A after bonding to the carrier submount and removal of the growth substrate.

FIG. 5A is a cross-sectional view of an LED chip that is similar to the LED chip of FIGS. 1A to 1F and further includes one or more support layers according to principles of the present disclosure.

FIG. 5B is a cross-sectional view at a subsequent fabrication step for the LED chip of FIG. 5A after bonding to the carrier submount and removal of the growth substrate.

FIG. 6 is a bottom view of an LED chip before the active LED structure is bonded to the carrier submount illustrating shapes of the anode and cathode contacts and corresponding shapes of anode and cathode mounting pads that reduce stress after bonding.

FIG. 7 is a view of an LED chip that is similar to the LED chip of FIG. 6 illustrating additional shapes of the anode and cathode contacts and anode and cathode mounting pads that reduce stress after bonding.

FIG. 8 is a view of an LED chip that is similar to the LED chip of FIG. 6 illustrating additional shapes of the anode and cathode contacts and anode and cathode mounting pads that reduce stress after bonding.

FIG. 9A is a view of an LED chip that is similar to the LED chip of FIG. 6 illustrating additional shapes of the anode and cathode contacts and anode and cathode mounting pads that reduce stress after bonding.

FIG. 9B is a cross-sectional view of a portion of the LED chip taken from the sectional line 9B-9B through the carrier submount of FIG. 9A.

FIG. 10 is a cross-sectional view of an LED chip that is similar to the LED chip of FIG. 6 illustrating additional shapes of the anode and cathode contacts, the anode and cathode mounting pads, and a multiple layer structure for the carrier submount that reduce stress after bonding.

FIG. 11A is a view of a portion of the carrier submount of FIG. 10 from a top view of a first layer of the carrier submount.

FIG. 11B is a view of a portion of the carrier submount of FIG. 10 from a top view of a second layer of the carrier submount.

FIG. 11C is a view of a portion of the carrier submount of FIG. 10 from a bottom view of a third layer of the carrier submount.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting devices and more particularly to contact structures for submounts in light-emitting diode (LED) devices. Exemplary devices include LED chips with active LED structures bonded to carrier submounts. Contact structures include arrangements of mounting pads of carrier submounts relative to contacts of active LED structures that improve bonding integrity and/or mitigate stress-related deformation in active LED structures where growth substrates are removed. Exemplary contact structures include differing heights between anode and cathode mounting pads, particularly greater heights for mounting pads with smaller surface areas to ensure suitable bonding contact. Additional contact structures include arrangements of contacts and corresponding mounting pads that position bonding interfaces about various areas of LED chips that mitigate and/or counterbalance certain areas prone to stress-related deformation.

Before delving into specific details of various aspects of the present disclosure, an overview of various elements that may be included in exemplary light-emitting devices of the present disclosure is provided for context. An LED chip typically comprises an active LED structure or region that may have many different semiconductor layers arranged in many different ways. The fabrication and operation of LEDs and their active structures are generally known in the art and are only briefly discussed herein. The layers of the active LED structure may be fabricated using known processes with a suitable process being metal organic chemical vapor deposition. The layers of the active LED structure typically comprise many different layers and generally comprise an active layer sandwiched between n-type and p-type oppositely doped epitaxial layers, all of which are formed successively on a growth substrate. It is understood that additional layers and elements may also be included in the active LED structure, including, but not limited to, buffer layers, nucleation layers, super lattice structures, un-doped layers, cladding layers, contact layers, and current-spreading layers and light extraction layers and elements. The active layer may comprise a single quantum well, a multiple quantum well, a double heterostructure, or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (AI), gallium (Ga), and indium (In). Gallium nitride (GaN) is a common binary compound. Group Ill nitrides also refer to ternary and quaternary compounds such as aluminum gallium nitride (AlGaN), indium gallium nitride (InGaN), and aluminum indium gallium nitride (AllnGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AllnGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm. In certain embodiments, LED chips may be covered with one or more lumiphoric materials, such as phosphors, such that at least some of the light from the active LED structure is absorbed by the one or more phosphors and is converted to one or more different wavelength spectra according to the characteristic emission from the one or more phosphors.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The present disclosure may be useful for LED chips having a variety of geometries, including flip-chip geometries. Flip-chip structures for LED chips typically include anode and cathode connections that are made from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate. In certain embodiments, the LED chip may be flip-chip mounted to a carrier submount and the growth substrate may then be removed.

According to aspects of the present disclosure, LED chips are formed by flip-chip mounting an active LED structure to a carrier submount by way of wafer level fabrication. By joining a bulk active LED structure to a carrier submount that includes electrical connections at the wafer level, individual LED chips and/or groupings thereof may be singulated with integrated electrical connections. The integrated electrical connections may provide more suitable bonding surfaces, such as generally symmetric shaped bonding pads, for mounting the LED chips in other LED packages and/or in LED fixtures. Wafer level fabrication may include bonding an LED wafer to a submount wafer before various light-emitting devices are singulated. As used herein, an LED wafer may include a growth substrate that has been blanket-deposited with an epitaxial LED structure. Individual LED chips along the growth substrate may be formed by post-epitaxy fabrication that may include removing portions of the epitaxial LED structures along streets to define boundaries of the LED chips. The LED wafer may include other post-epitaxy fabrication, such as formation of reflective structures, anode and cathode electrical contacts for each LED chip, and/or passivation layers, among others. As used herein, a submount wafer may include ceramic materials such as aluminum oxide or alumina, silicon nitride, AlN, or organic insulators like PI and PPA, or a PCB, sapphire, Si or any other suitable material. As described below in greater detail, metal trace patterns may be provided on one or more sides of the submount for receiving and/or electrically connecting with one or more LED chips of the LED wafer. A submount wafer may form a precursor structure that when subdivided along with the LED wafer, provides a separate carrier submount for each LED chip.

Various aspects as described herein are provided in the context of anode and cathode structures. It is understood the principles are equally applicable to reverse configurations by reversing the order of anode and cathode structures as described herein. Accordingly, anode contacts, anode mounting pads, and anode bond pads as described below in greater detail may be generally referred to as first contacts, first mounting pads, and first bond pads for polarity agnostic disclosure. In a similar manner, cathode contacts, cathode mounting pads, and cathode bond pads as described below in greater detail may be generally referred to as second contacts, second mounting pads, and second bond pads according to principles of the present disclosure.

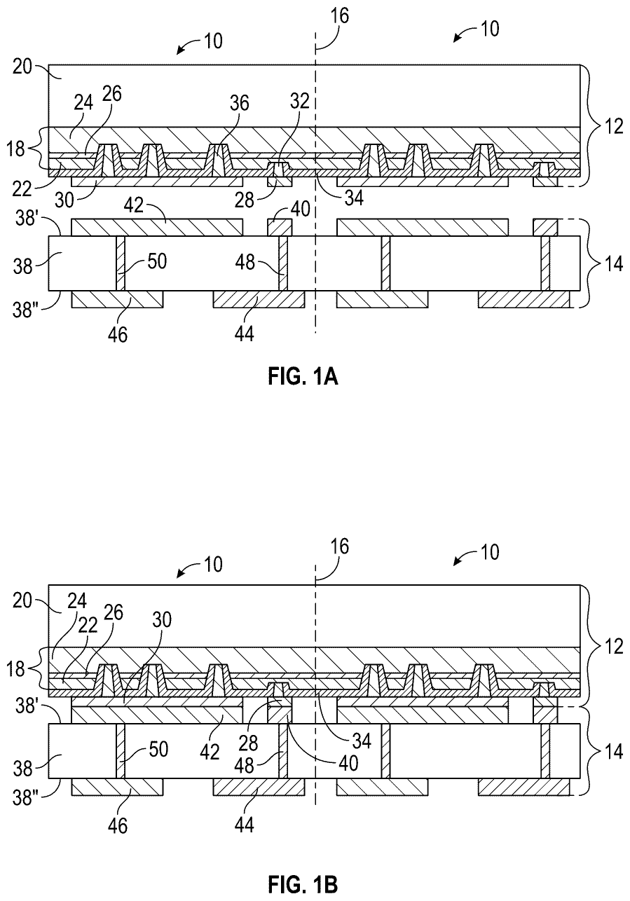

FIG. 1A is a cross-sectional view at a fabrication step for forming LED chips 10 at the wafer level. In FIG. 1A, an LED wafer 12 is positioned for mounting to a submount wafer 14. For illustrative purposes, the view provided in FIG. 1A shows only two LED chips 10 before singulation, and superimposed vertical dashed lines 16 indicate locations where individual LED chips 10 will later be separated. In practice, the quantity of LED chips 10 formed may be much higher.

The LED wafer 12 includes an active LED structure 18 on a growth substrate 20. The active LED structure 18 generally refers to portions of the LED chip 10 that include semiconductor layers, such as epitaxial semiconductor layers, that form a structure that generates light when electrically activated. The active LED structure 18 may generally comprise a p-type layer 22, an n-type layer 24, and an active layer 26 arranged between the p-type layer 22 and the n-type layer 24. The active LED structure 18 may include many additional layers such as, but not limited to, buffer layers, nucleation layers, super lattice structures, undoped layers, cladding layers, contact layers, current-spreading layers, and light extraction layers and elements. In various embodiments, the active layer 26 may comprise a single quantum well, a multiple quantum well, a double heterostructure, or super lattice structures. The active LED structure 18 may initially be formed by epitaxially growing or depositing the n-type layer 24, the active layer 26, and the p-type layer 22 sequentially on the growth substrate 20.

The LED chips 10 may further include an anode contact 28 and a cathode contact 30 for mounting to the submount wafer 14. The anode contact 28 is electrically coupled to the p-type layer 22 by way of vias 32 that extend through a passivation layer 34, and the cathode contact 30 is electrically coupled to the n-type layer 24 by way of vias 36 that may also extend through the passivation layer 34. Certain chip structures include anode contacts 28 with different shapes than cathode contacts 30. As illustrated in FIG. 1A, the cathode contact 30 is substantially larger than the anode contact 28. In other embodiments, the order may be reversed such that the anode contact 28 is substantially larger than the cathode contact 30. While having differently shaped anode and cathode contacts 28, 30 may be advantageous in certain LED chip structures, certain LED applications may prefer more symmetrically shaped anode and cathode contacts 28, 30.

The submount wafer 14 includes a carrier submount 38 with anode and cathode mounting pads 40, 42 on a first side 38′, or frontside, of the carrier submount 38. An anode bond pad 44 and a cathode bond pad 46 for each LED chip 10 is arranged on a second side 38″, or backside, of the carrier submount 38. Corresponding vias 48 within the carrier submount 38 electrically couple the anode mounting pad 40 to the anode bond pad 44, and other vias 50 within the carrier submount 38 electrically couple the cathode mounting pad 42 to the cathode bond pad 46. The anode and cathode mounting pads 40, 42 may embody patterned metal traces on the first side 38′, and the anode and cathode bond pads 44, 46 may embody patterned metal traces on the second side 38″. As illustrated, the arrangement of the submount wafer 14 provides anode and cathode mounting pads 40, 42 that correspond to the shape of the anode and cathode contacts 28, 30 of the LED chips 10, and anode and cathode bond pads 44, 46 with different and more symmetric shapes for improved bonding to other surfaces in various applications.

FIG. 1B is a cross-sectional view at a subsequent fabrication step to FIG. 1A where the LED wafer 12 is bonded to the submount wafer 14. A wafer aligner may be employed to correctly position the LED wafer 12 relative to the submount wafer 14 so the anode contacts 28 may be aligned with and mounted to the anode mounting pads 40 and the cathode contacts 30 may be aligned with and mounted to the cathode mounting pads 42. Such wafer bonding may be provided by various techniques that mechanically and electrically bond metals of each anode contact 28 and each cathode contact 30 with metals of corresponding anode and cathode mounting pads 40, 42. For example, bonding may include thermocompression bonding of certain same metals, such as gold (Au), copper (Cu), or aluminum (AI), among others, that are present at interfaces formed between the anode or cathode contacts 28, 30, and the corresponding anode and cathode mounting pads 40, 42. Other bonding may involve die attach metal stacks formed at the interfaces, such as eutectic metal stacks including gold-tin (Au—Sn), gold-silicon (Au—Si), gold-germanium (Au—Ge), aluminum-germanium (Al—Ge), or gold-indium (Au—In), among others. Still further bonding may involve transient liquid phase bonding with copper-tin (Cu—Sn), Au—In, or silver-tin (Ag—Sn), among others. Additional bonding may involve bump bonding by way of a pattern of solder bumps or by way of solder paste bonding.

FIG. 1C is a cross-sectional view at a subsequent fabrication step to FIG. 1B where the growth substrate 20 of FIG. 1B is removed from the LED wafer 12. The growth substrate 20 of FIG. 1B may be removed by various subtractive processes, such as laser lift off or mechanical grinding, among others. While not drawn to scale, it is understood the active LED structure 18 and remaining portions of the LED wafer 12 may be substantially thinner than the submount wafer 14 after removal of the growth substrate 20 of FIG. 1B. In this regard, the active LED structure 18 in FIG. 1C is mechanically supported by the underlying carrier submount 38 by way of metal bonding the anode and cathode contacts 28, 30 with the corresponding anode and cathode mounting pads 40, 42.

FIG. 1D is a cross-sectional view at a subsequent fabrication step to FIG. 1C where a top surface 24′ of the n-type layer 24 forms a primary light-extracting face for each LED chip 10. In certain embodiments, the top surface 24′ may comprise a textured or patterned surface for improving light extraction. The texturing or patterning may be provided by way of etching, imprinting, or associated features from embodiments where the growth substrate 20 of FIG. 1B is patterned before epitaxial growth.

FIG. 1E is a cross-sectional view at a subsequent fabrication step to FIG. 1D where individual LED chips 10 are separated from one another. As illustrated, each individual LED chip 10 includes the active LED structure 18 flip-chip mounted to the corresponding carrier submount 38. The LED chips 10 may be separated by various singulation techniques, including laser singulation and/or mechanical sawing, followed by tape-stretching the LED chips 10 apart.

FIG. 1F is a bottom view of one of the LED chips 10 from FIG. 1E. As illustrated, the anode and cathode bond pads 44, 46 are shaped for improved mounting to other surfaces as compared to the asymmetry between the anode and contacts 28, 30 of FIG. 1E. The anode and cathode bond pads 44, 46 may generally be symmetric to one another. In still further embodiments, one of the anode and cathode bond pads 44, 46 may have a slightly different shape, such as a notch or a cut-out for polarity indication.

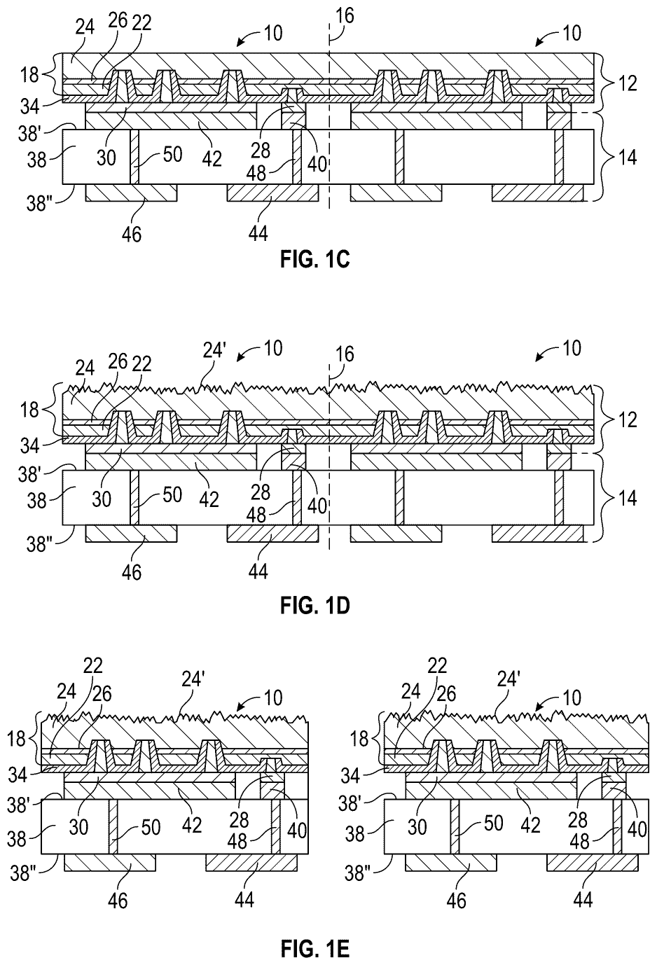

FIG. 2 is a cross-sectional view of an exemplary one of the LED chips of FIGS. 1A to 1F that exhibits stress-related deformation. Various elements of the LED chip 10 described above for FIGS. 1A to 1F are omitted for illustrative purposes. As described above, the thickness of the active LED structure 18 relative to the carrier submount 38 is not drawn to scale. In practice, the active LED structure 18 is substantially thinner than the carrier submount 38. For example, the active LED structure 18 may be so thin as to be considered a generally two-dimensional structure as compared to the three-dimensional bulk structure of the carrier submount 38. After the removal of the growth substrate described above from FIG. 1B to 1C, stress and/or strain within the epitaxial layers of the active LED structure 18 may cause deformation. For example, the active LED structure 18 may tend to bow from center portions of the carrier submount 38 such that perimeter edges of the active LED structure 18 deform away from the carrier submount 38. In certain instances, the active LED structure 18 may even delaminate along one or more of the perimeter edges, thereby interfering with integrity of electrical connections between the anode and contacts 28, 30 and the anode and cathode mounting pads 40, 42. As illustrated in FIG. 2, the narrow shape of the anode contact 28 and corresponding anode mounting pad 40 may provide full separation during deformation. In other applications, deformation of the active LED structure 18 may occur in different directions, such as an inverse bow from what is depicted in FIG. 2 where center portions of the active LED structure 18 may deform away from the carrier submount 38.

According to aspects of the present disclosure, various contact structures for the carrier submounts are described that mitigate deformation of active LED structures after growth substrate removal. In certain embodiments, contact structures include greater heights of anode mounting pads relative to cathode mounting pads. In this manner, smaller anode contacts of LED wafers may first contact corresponding anode mounting pads before cathode contacts make contact with corresponding cathode mounting pads to ensure sufficient bonding. In other embodiments, anode and cathode contacts of LED wafers and corresponding mounting pads of submount wafers may have different shapes that break up gaps between anode and cathode contacts near center regions to more evenly balance stress and reduce deformation.

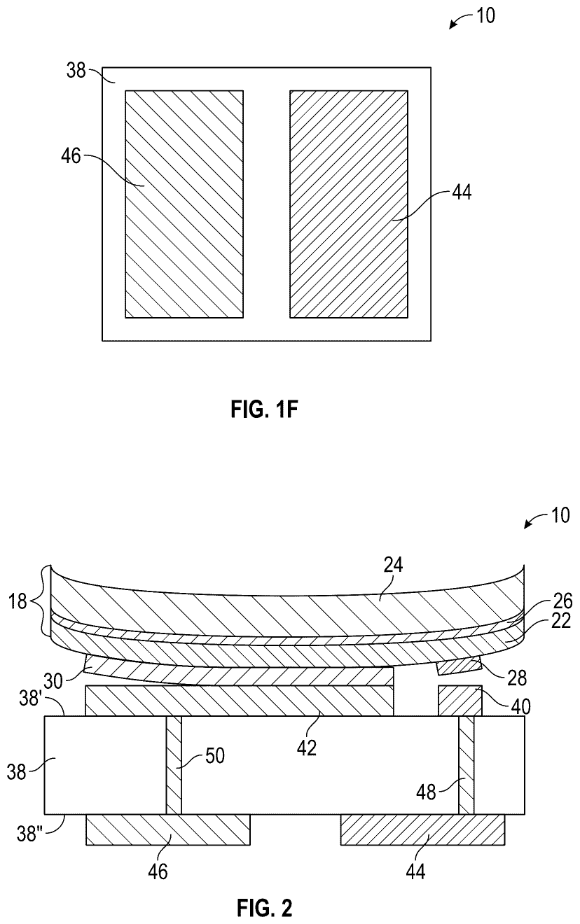

FIG. 3A is a cross-sectional view of an LED chip 52 that is similar to the LED chip 10 of FIGS. 1A to 1F except the anode mounting pad 40 is formed with increased thickness relative to the cathode mounting pad 42. FIG. 3A corresponds to a fabrication step similar to FIG. 1A before the active LED structure 12 is bonded to the carrier submount 38. FIG. 3B is a cross-sectional view at a subsequent fabrication step for the LED chip 52 after bonding to the carrier submount 38 and removal of the growth substrate 20. FIG. 3B corresponds to a fabrication step similar to FIG. 1C. For illustrative purposes, one LED chip 52 is illustrated. In practice, any number of LED chips 52 may be formed at the wafer level in the same manner described above for FIGS. 1A to 1E. As illustrated, the anode contact 28 and the cathode contact 30 are formed with a substantially same thickness relative to the active LED structure 18. In certain embodiments, the passivation layer 34 forms a generally planar surface for the anode and cathode contacts 28, 30 such that they are formed in a same deposition step and have a substantially same thickness, within a half percent margin of error. However, a height H1 of the anode mounting pad 40 is greater than a corresponding height H2 of the cathode mounting pad 42 above the carrier submount 38. Accordingly, as the active LED structure 18 is moved closer to the carrier submount 38 for bonding, the anode contact 28 will make contact with the anode mounting pad 40 before the cathode contact 30 makes contact with the cathode mounting pad 42. In this manner, sufficient bonding may occur between the smaller area anode contact 28 and anode mounting pad that may mitigate deformation of the active LED structure 18 after removal of the growth substrate 20.

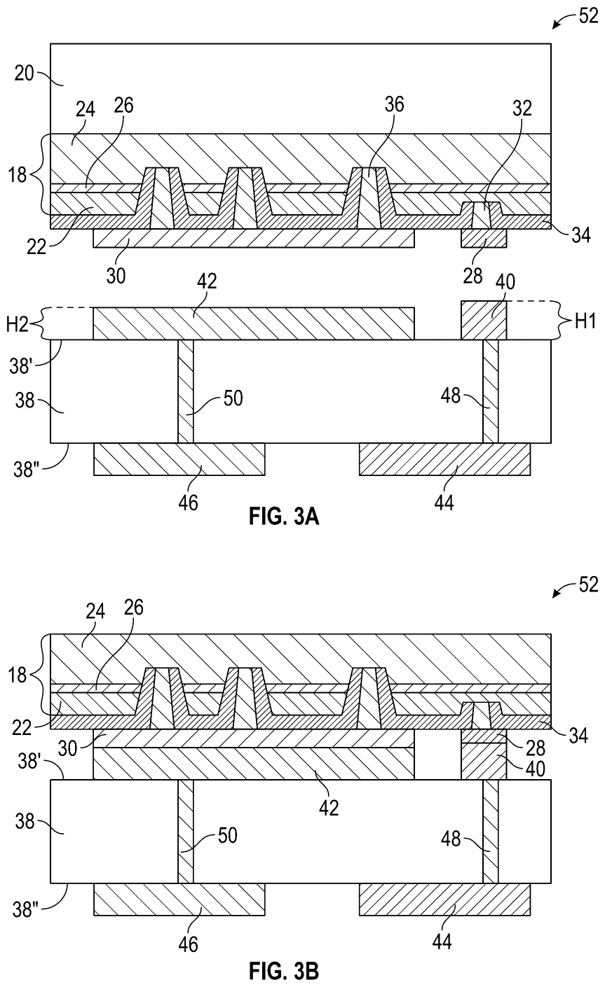

FIG. 4A is a simplified cross-sectional view of the LED chip 52 of FIGS. 3A and 3B with an enlarged portion illustrating further details of the anode and cathode mounting pads 40, 42. FIG. 4A corresponds to a fabrication step similar to FIG. 3A before the active LED structure 18 is bonded to the carrier submount 38. In certain embodiments, each of the anode mounting pad 40 and the cathode mounting pad 42 may include a base layer 54 with a protective layer 56. The base layer 54 may comprise various materials, such as Cu. As illustrated, the base layer 54 is responsible for most of the heights H1 and H2 of the anode and cathode mounting pads 40, 42. In this manner, the difference between the heights H1 and H2 may be controlled by relative differences in height of the base layers 54. In one example, the height difference between H1 and H2 may be a result of a difference in height such that the base layer 54 of the anode mounting pad 40 is at least 2% thicker than a height of the base layer 54 of the cathode mounting pad 42. By way of example, the height H2 may be about 50 microns (μm) while the height H1 may be about 51 to 52 μm. The protective layer 56 may comprise a metal that provides environmental protection for the underlying base layer 54 and facilitates eutectic bonding with the anode and cathode contacts 28, 30. For example, the protective layer 56 may embody protective plating such as electroless nickel electroless palladium immersion gold (ENEPIG), electroless nickel immersion gold (ENIG), or a titanium-gold layer, among others.

FIG. 4B is a cross-sectional view at a subsequent fabrication step for the LED chip 52 of FIG. 4A after bonding to the carrier submount 38 and removal of the growth substrate 20. In certain embodiments, bonding interfaces 58-1 and 58-2 are formed between the protective layers 56 and corresponding anode and cathode contacts 28, 30. For example, the bonding interfaces 58-1 and 58-2 may embody eutectic bonding interfaces identifiable by the presence of the materials of the protective layers 56. As illustrated, a position of the bonding interface 58-1 may be defined by the height H1 of the anode mounting pad 40, and a position of the bonding interface 58-2 may be defined by the height H2 of the cathode bonding pad 42. By forming the height H1 to be greater than the height H2, physical contact between the anode contact 28 and the anode mounting pad 40 may occur first during bonding to ensure the bonding interface 58-1 has improved mechanical integrity.

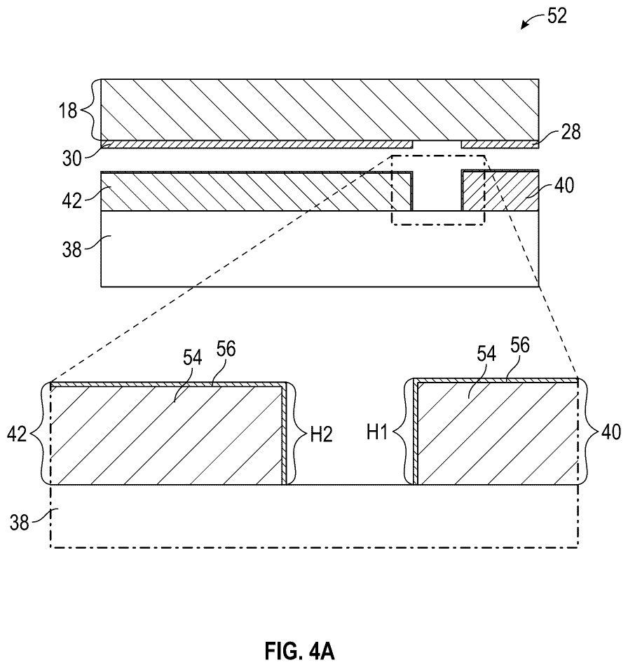

FIG. 5A is a cross-sectional view of an LED chip 60 that is similar to the LED chip 10 of FIGS. 1A to 1F and further includes one or more support layers 62-1, 62-2 according to principles of the present disclosure. FIG. 5A corresponds to a fabrication step similar to FIG. 1A before the active LED structure 18 is bonded to the carrier submount 38. FIG. 5B is a cross-sectional view at a subsequent fabrication step for the LED chip 60 after bonding to the carrier submount 38 and removal of the growth substrate 20. FIG. 5B corresponds to a fabrication step similar to FIG. 1C. For illustrative purposes, one LED chip 60 is illustrated. In practice, any number of LED chips 60 may be formed at the wafer level in the same manner described above for FIGS. 1A to 1E. The one or more support layers 62-1, 62-2 may embody conformal insulating materials that effectively fill in topography differences proximate the anode and cathode contacts 28, 30 and the anode and cathode mounting pads 40, 42. The support layers 62-1, 62-2 may be separately provided on the active LED structure 18 and the carrier submount 38 before bonding as illustrated in FIG. 5A. Once bonded as illustrated in FIG. 5B, the support layers 62-1, 62-2 may effectively be joined together to fill gaps between the active LED structure 18 and the carrier submount 38. In this manner, the support layers 62-1, 62-2 may serve to evenly distribute mechanical stress during bonding and/or provide additional anchoring to provided improved bonding strength with reduced deformation of the active LED structure 18. The support layers 62-1, 62-2 may comprise polymer-based materials such as epoxy-based negative photoresists (e.g., SU-8), benzocyclobutene (BCB), silicone, and other dielectrics such as SiO₂, Al₂O₃, and TiO₂. In certain embodiments, the one or more support layers 62-1, 62-1 as described above for FIGS. 5A and 5B may be implemented in combination with the embodiments of the LED chip 52 of FIGS. 3A to 4B.

In addition to the above-described embodiments of the LED chip 52 of FIGS. 3A to 4B and the LED chip 60 of FIGS. 5A to 5B, further principles of the present disclosure include layouts of contact structures that reduce and/or prevent deformation of active LED structures as illustrated in FIG. 2. Bonding interfaces between anode contacts and anode mounting pads and between cathode contacts and cathode mounting pads effectively embody anchoring locations. As will be described below in greater detail, contact structure layouts include shapes for anode and cathode contacts and corresponding shapes for anode and cathode mounting pads that counterbalance stress in active LED structures away from common inflection areas.

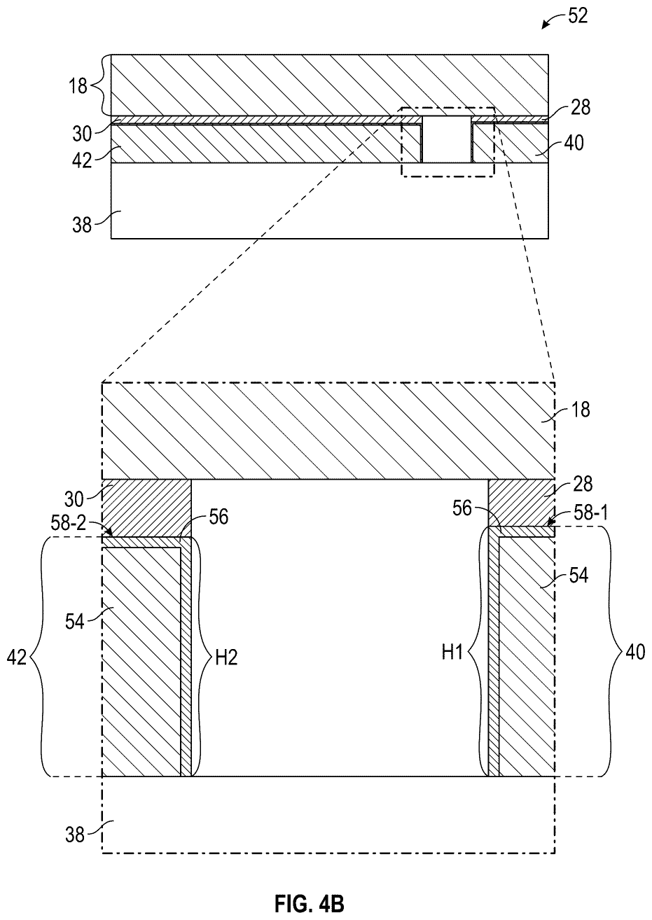

FIG. 6 is a view of an LED chip 64 before the active LED structure 18 is bonded to the carrier submount 38 illustrating shapes of the anode and cathode contacts 28, 30 and corresponding shapes of anode and cathode mounting pads 40, 42 that reduce stress after bonding. FIG. 6 provides a bottom view of the active LED structure 18 and a top view of the carrier submount 38. A superimposed dashed line arrow indicates a direction for flipping the active LED structure 18 to the carrier submount 38 for bonding. In this manner, the anode contact 28 will be bonded to the anode mounting pad 40, and the cathode contact 30 will be bonded to the cathode mounting pad 42 as described above.

In FIG. 6, the anode and cathode contacts 28, 30 each cover relatively large areas of the active LED structure 18 with a gap 66 therebetween, and the anode and cathode mounting pads 28, 30 each cover corresponding areas of the carrier submount 38 with a gap 68 therebetween. The gaps 66, 68 correspond to areas without metalized bonding and associated anchoring after the active LED structure 18 is bonded to the carrier submount 38. As illustrated, the anode and cathode contacts 28, 30 are formed with shapes that include interdigitated fingers that form the gaps 66, 68. In this manner, the gap 66 forms a nonlinear gap that traverses from one perimeter edge of the anode and cathode contacts 28, 30 to an opposing perimeter edge of the anode and cathode contacts 28, 30. The gap 68 is formed in corresponding manner on the carrier submount 38. By forming the gaps 66, 68 in a nonlinear manner across the LED chip 64, areas that are not anchored from bonding (i.e., the gaps 66, 68) are effectively distributed in a nonlinear manner to counterbalance stress in the active LED structure 18 after bonding.

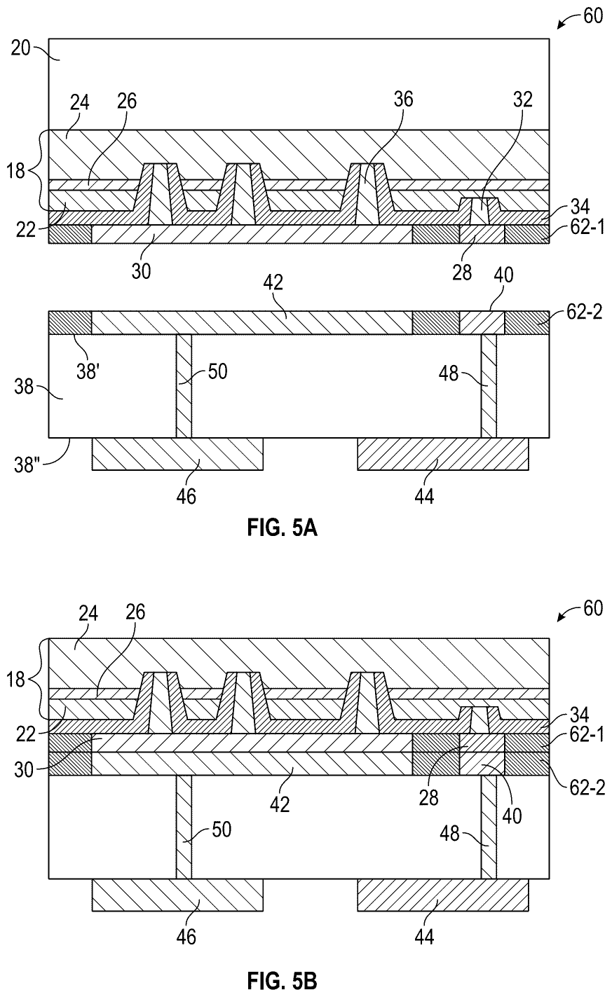

FIG. 7 is a view of an LED chip 70 that is similar to the LED chip 64 of FIG. 6 illustrating additional shapes of the anode and cathode contacts 28, 30 and anode and cathode mounting pads 40, 42 that reduce stress after bonding. Instead of the interdigitated finger structure of FIG. 6, the anode and cathode contacts 28, 30 have facing edges that form wavy lines to provide the nonlinear shape of the gap 66. In certain embodiments, the gap 66 is continuously curved between opposing perimeter edges of the anode and cathode contacts 28, 30. The anode and cathode mounting pads 40, 42 and the gap 68 are formed in a corresponding manner on the carrier submount 38.

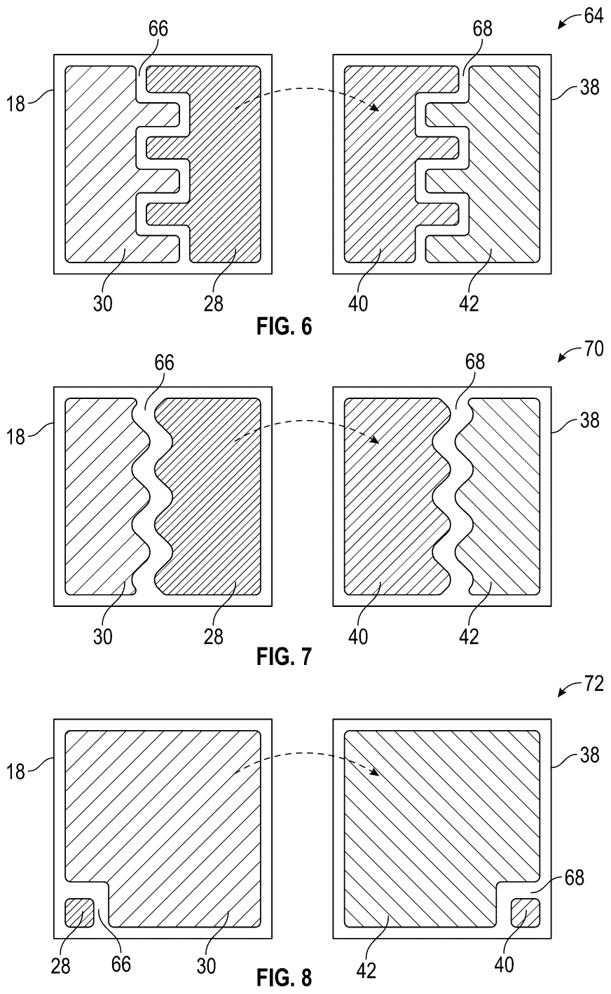

FIG. 8 is a view of an LED chip 72 that is similar to the LED chip 64 of FIG. 6 illustrating additional shapes of the anode and cathode contacts 28, 30 and anode and cathode mounting pads 40, 42 that reduce stress after bonding. In FIG. 8, the anode contact 28 forms a small square proximate a corner of the active LED structure 18, and the cathode contact 30 covers a substantially larger portion, extending along a majority of three edges of the LED chip 72. The gap 66 thereby extends in a nonlinear manner adjacent connecting perimeter edges of the LED chip 72. In certain embodiments, the gap 66 may form two connecting linear sub-portions that follow the anode contact 28 such that the overall gap 66 is nonlinear. The anode and cathode mounting pads 40, 42 and the gap 68 are formed in corresponding manner on the carrier submount 38. In this manner, anchoring is provided between the cathode contact 30 and the cathode mounting pad 42 across a substantial majority of the LED chip 72.

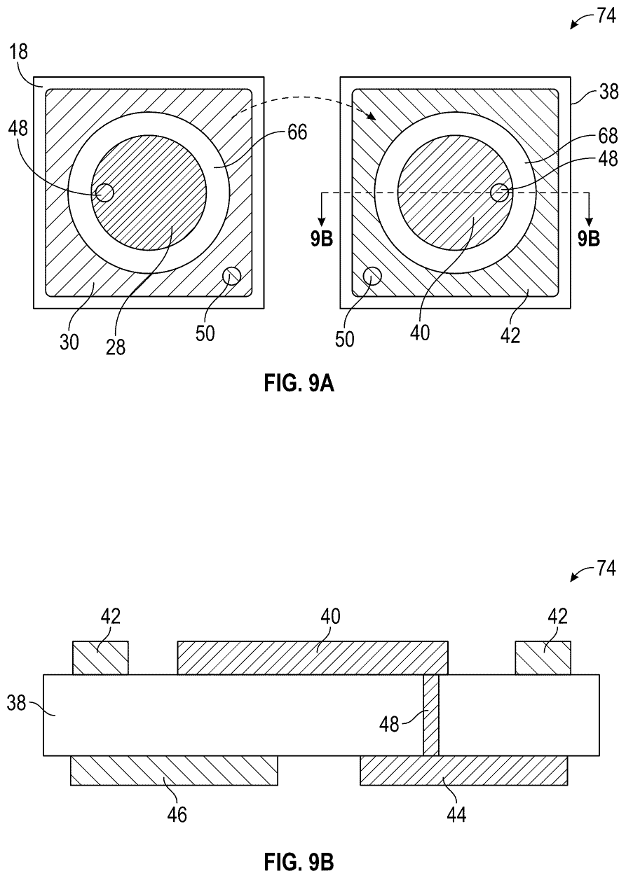

FIG. 9A is a view of an LED chip 74 that is similar to the LED chip 64 of FIG. 6 illustrating additional shapes of the anode and cathode contacts 28, 30 and anode and cathode mounting pads 40, 42 that reduce stress after bonding. FIG. 9B is a cross-sectional view of a portion of the LED chip 74 taken from the sectional line 9B-9B through the carrier submount 38 of FIG. 9A. As illustrated, the anode contact 28 and anode mounting pad 40 are formed with circular shapes that radially curve around a center of the LED chip 74. The cathode contact 30 and the cathode mounting pad 42 extend to surround perimeter edges of the anode contact 28 and the anode mounting pad 40. In this manner, the cathode contact 30 extends between the anode contact 28 and all perimeter edges of the active LED structure 18, and the cathode mounting pad 42 extends in a similar manner relative to the carrier submount 38. Accordingly, the gaps 66, 68 are nonlinear gaps that curve in positions laterally spaced from the center of the LED chip 74. In this manner, the radial nature of the gaps 66, 68 may reduce stress effects that may otherwise contribute to cupping or bowing about the center of the active LED structure 18 as illustrated in FIG. 2. As further illustrated in FIGS. 9A and 9B, positions of the vias 48 and 50 are provided.

In certain embodiments, the shapes of anode and cathode contacts 28, and anode and cathode mounting pads 40, 42 for reducing stress in the active LED structure 18 may be implemented in combination with the embodiments as described above for the LED chip 52 of FIGS. 3A to 4B and/or the LED chip 60 of FIGS. 5A and 5B.

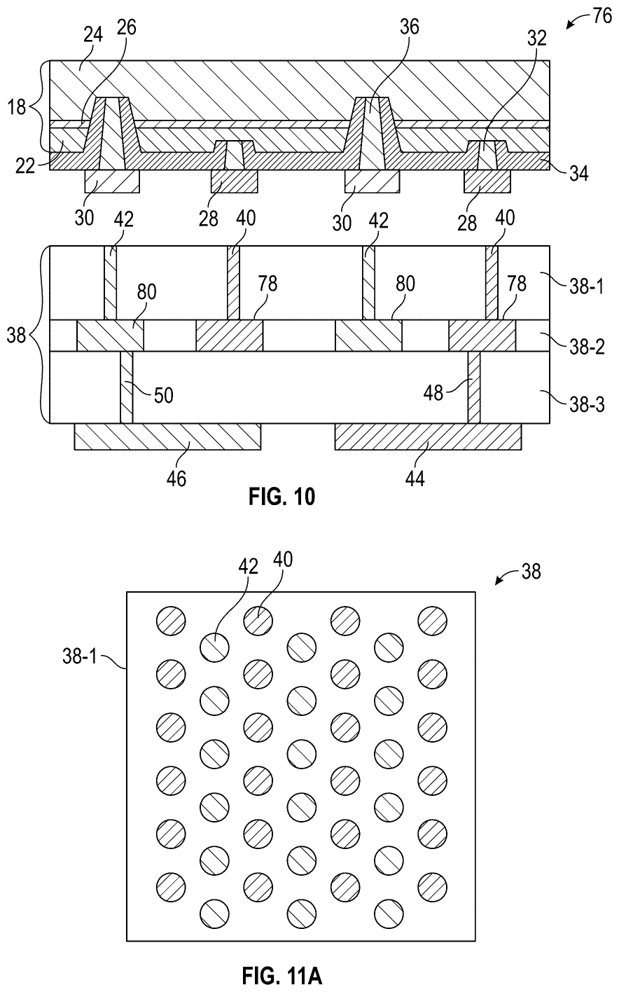

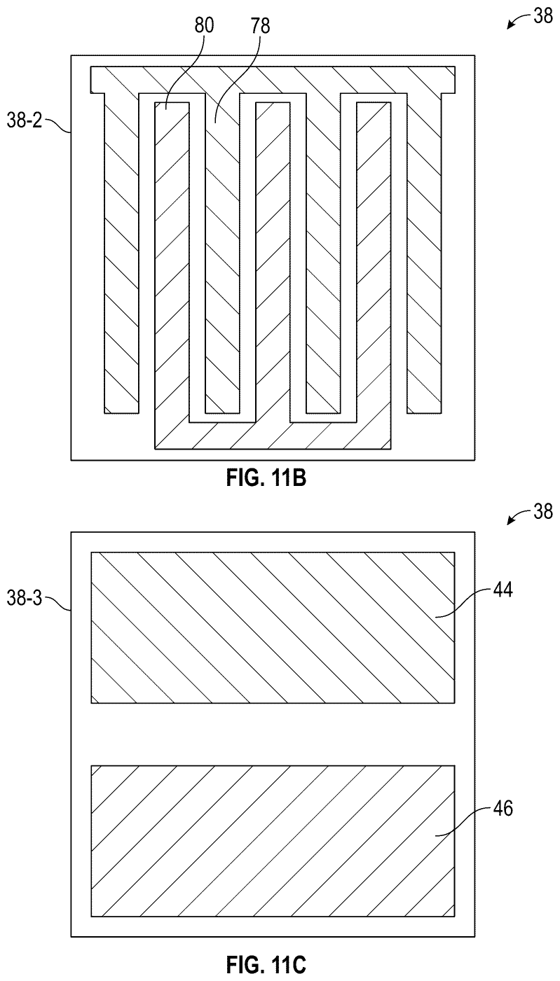

FIG. 10 is a cross-sectional view of an LED chip 76 that is similar to the LED chip 64 of FIG. 6 illustrating additional shapes of the anode and cathode contacts 28, 30, the anode and cathode mounting pads 40, 42, and a multiple layer structure for the carrier submount 38 that reduce stress after bonding. FIG. corresponds to a fabrication step similar to FIG. 1A before the active LED structure 18 is bonded to the carrier submount 38. As illustrated, the LED chip 76 includes a plurality of anode and cathode contacts 28, 30 distributed across the LED chip 76. In this manner, multiple bonding areas may be formed in an array across the LED chip 76 for counterbalancing stress in the active LED structure 18. As further illustrated in FIG. 10, the carrier submount 38 may be subdivided into multiple layers 38-1 to 38-3. A first layer 38-1 includes the anode and cathode mounting pads 40, 42 for mounting with the anode and cathode contacts 28, 30. In certain embodiments, the anode and cathode mounting pads 40, 42 extend entirely through the first layer 38-1. A second layer 38-2 includes at least one anode interconnection 78 that electrically interconnects anode mounting pads 40 and at least one cathode interconnection 80 that electrically interconnects the cathode mounting pads 42 at an interface between the first and second layers 38-1, 38-2. In FIG. 10, it is appreciated that the at least one anode interconnection 78 and the at least one cathode interconnection 80 may each form single structures that respectively extend continuously out of a plane of view with respect to the cross-section of FIG. 10. This will be described and illustrated in greater detail below for FIG. 11B. A third layer 38-3 includes the vias 48, 50 that electrically connect the anode and cathode interconnections 78, 80 with the anode and cathode bond pads 44, 46 on a bottom of the LED chip 76. In this manner, the carrier submount 38 forms a structure that effectively forms an array of anode and cathode mounting positions for the active LED structure 18 that are routed to the generally symmetrically shaped anode and cathode bond pads 44, 46.

FIGS. 11A to 11C collectively illustrate an exemplary layout and structure for the various layers 38-1 to 38-3 of the carrier submount of FIG. 10.

FIG. 11A is a view of a portion of the carrier submount 38 of FIG. 10 from a top view of the first layer 38-1 for an exemplary layout of the carrier submount 38. As illustrated, the anode and cathode mounting pads 40, 42 may form an array across an area of the carrier submount 38 (and LED chip 76 of FIG. 10). In certain embodiments, the anode and cathode mounting pads 40, 42 may form in alternating columns. In a similar manner, the anode and cathode contacts 28, 30 for the active LED structure 18 of FIG. 10 may have a corresponding shape.

FIG. 11B is a view of a portion of the carrier submount 38 of FIG. 10 from a top view of the second layer 38-2 of the carrier submount 38. As illustrated, the anode interconnection 78 may form a continuous structure with various finger extensions across the second layer 38-2, and the cathode interconnection 80 may also form a continuous structure with various finger extensions across the second layer 38-2. In certain embodiments, the finger extensions of the anode interconnection 78 may be arranged in an interdigitated arrangement with the finger extensions of the cathode interconnection 80 to make contact with the alternating columns of the anode and cathode mounting pads 40, 42 of FIG. 11A.

FIG. 11C is a view of a portion of the carrier submount 38 of FIG. 10 from a bottom view of the third layer 38-3 of the carrier submount 38. In certain embodiments, the anode and cathode bond pads 44, 46 form generally symmetrically shapes to provide more robust mounting of corresponding LED chips to other surfaces.

In certain embodiments, the principles described above for the anode and cathode contacts 28, 30 and the multiple layer structure of the carrier submount 38 of FIGS. 10 to 11C may be implemented in combination with the embodiments for the LED chip 52 of FIGS. 3A to 4B, the LED chip 60 of FIGS. 5A and 5B, the LED chip 64 of FIG. 6, the LED chip 70 of FIG. 7, the LED chip 72 of FIG. 8, and the LED chip 74 of FIGS. 9A to 9B.

It is further contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
a carrier submount comprising a first mounting pad and a second mounting pad, the first mounting pad having a height above the carrier submount that is greater than a height of the second mounting pad above the carrier submount;
an active LED structure bonded to the carrier submount, the active LED structure comprising an n-type layer, a p-type layer, and an active layer between the n-type layer and the p-type layer;
a first contact electrically coupled to either the p-type layer or the n-type layer, the first contact being bonded to the first mounting pad in a position that is between the active LED structure and the carrier submount; and
a second contact electrically coupled to one of the p-type layer or the n-type layer that is different from the first contact, the second contact being bonded to the second mounting pad in a position that is between the active LED structure and the carrier submount.

2. The LED chip of claim 1, wherein a thickness of the first contact is the same as or differs by no more than one half percent of a thickness of the second contact relative to the active LED structure.

3. The LED chip of claim 2, wherein the first contact is an anode contact electrically coupled to the p-type layer and the second contact is a cathode contact electrically coupled to the n-type layer.

4. The LED chip of claim 3, further comprising an anode bond pad and a cathode bond pad on a side of the carrier submount that is opposite the active LED structure, wherein the anode bond pad forms a shape that is symmetric with the cathode bond pad.

5. The LED chip of claim 1, wherein the first mounting pad and the second mounting pad each comprise a base layer and a protective layer on the base layer.

6. The LED chip of claim 5, wherein:
the protective layer of the first mounting pad forms a first bonding interface with the first contact;
the protective layer of the second mounting pad forms a second bonding interface with the second contact; and
a position of the first bonding interface above the carrier submount is greater than a position of the second bonding interface above the carrier submount.

7. The LED chip of claim 1, further comprising an insulating support layer between the carrier submount and the active LED structure, the insulating support layer positioned between the first and second contacts.

8. A light-emitting diode (LED) chip, comprising:
a carrier submount comprising a first mounting pad and a second mounting pad;
an active LED structure bonded to the carrier submount, the active LED structure comprising an n-type layer, a p-type layer, and an active layer between the n-type layer and the p-type layer;
a first contact electrically coupled to the active LED structure, the first contact being bonded to the first mounting pad; and
a second contact electrically coupled to active LED structure, the second contact being bonded to the second mounting pad;
the first contact and the second contact forming a nonlinear gap therebetween, the nonlinear gap extending continuously to segregate the first contact from the second contact.

9. The LED chip of claim 8, wherein the first contact and the second contact form interdigitated fingers, and the nonlinear gap extends from one perimeter edge of the first contact to an opposing perimeter edge of the first contact along the interdigitated fingers.

10. The LED chip of claim 9, wherein the first mounting pad and the second mounting pad form corresponding interdigitated fingers.

11. The LED chip of claim 8, wherein the nonlinear gap is continuously curved between opposing perimeter edges of the first contact.

12. The LED chip of claim 8, wherein the first contact is positioned proximate a corner of the active LED structure, and the second contact extends proximate a majority of three perimeter edges of the active LED structure.

13. The LED chip of claim 8, wherein the nonlinear gap is radially curved about a center of the active LED structure.

14. The LED chip of claim 13, wherein the nonlinear gap is radially curved to from a circular shape.

15. The LED chip of claim 8, further comprising a first bond pad and a second bond pad on a side of the carrier submount that is opposite the active LED structure, wherein the first bond pad forms a shape that is symmetric with the second bond pad.

16. A light-emitting diode (LED) chip, comprising:
a carrier submount comprising a plurality of layers, the plurality of layers comprising:
a first layer with at least one anode mounting pad and at least one cathode mounting pad;
a second layer with at least one anode interconnection electrically coupled to the at least one anode mounting pad and at least one cathode interconnection electrically coupled to the at least one cathode mounting pad; and
a third layer with an anode bond pad electrically coupled to the at least one anode interconnection and a cathode bond pad electrically coupled to the at least one cathode interconnection;
an active LED structure bonded to the carrier submount;
at least one anode contact electrically coupled between the active LED structure and the at least one anode mounting pad; and
at least one cathode contact electrically coupled between the active LED structure and the at least one cathode mounting pad.

17. The LED chip of claim 16, wherein:
the at least one anode mounting pad comprises a plurality of anode mounting pads that form a first array across the first layer;
the at least one anode contact comprises a plurality of anode contacts that are bonded to the plurality of anode mounting pads;
the at least one cathode mounting pad comprises a plurality of cathode mounting pads that form a second array across the first layer; and
the at least one cathode contact comprises a plurality of cathode contacts that are bonded to the plurality of cathode mounting pads.

18. The LED chip of claim 17, wherein:
the at least one anode interconnection forms a continuous structure electrically coupled to each anode mounting pad of the plurality of anode mounting pads; and
the at least one cathode interconnection forms a continuous structure electrically coupled to each cathode mounting pad of the plurality of cathode mounting pads.

19. The LED chip of claim 18, wherein:
the at least one anode interconnection forms a first plurality of finger extensions; and
the at least one cathode interconnection a second plurality of finger extensions that are interdigitated with the first plurality of finger extensions.

20. The LED chip of claim 16, wherein the anode bond pad forms a shape that is symmetric with the cathode bond pad.
